(19) United States
(12) Patent Application Publication
(10) Pub. No.: US 2006/0238185 A1
(43) Pub. Date: Oct. 26, 2006

(54) Probe storage device, system including the device, and methods of forming and using same

(76) Inventor: Michael N. Kozicki, Phoenix, AZ (US)

Correspondence Address: SNELL & WILMER, 400 EAST VAN BUREN, ONE ARIZONA CENTER, PHOENIX, AZ, 85004-2202, US

(21) Appl. No.: 11/401,801

(22) Filed: Apr. 10, 2006

Related U.S. Application Data
(60) Provisional application No. 60/669,556, filed on Apr. 8, 2005.

(51) Int. Cl. G01R 19/00

(52) U.S. Cl. 324/66

(57) ABSTRACT

A probe storage system, including programmable cells suitable for storing information, and methods of forming and programming the cells are disclosed. The programmable cells generally include an ion conductor and a plurality of electrodes, wherein one of the electrodes may be in the form of a probe. Electrical properties of the cells may be altered by applying energy to the structure, and thus information may be stored using the system.

### CROSS REFERENCE TO RELATED APPLICATIONS

This application claims the benefit of U.S. Patent Application Ser. No. 60/669,556, entitled DATA STORAGE IN SOLID ELECTROLYTE FILMS BY SCANNING PROBE TECHNIQUES, filed Apr. 8, 2005, the contents of which are incorporated herein by reference.

### FIELD OF INVENTION

The present invention generally relates to data storage devices and systems, and more particularly, to devices suitable for probe data storage, systems including the devices, and methods of forming and using the devices and systems.

### BACKGROUND OF THE INVENTION

Memory devices are often used in electronic systems and computers to store information in the form of binary data. These memory devices may be characterized into various types, each type having associated with it various advantages and disadvantages.

For example, random access memory (“RAM”), which may be found in personal computers, is typically volatile semiconductor memory; in other words, the stored data is lost if the power source is disconnected or removed. Dynamic RAM (“DRAM”) is particularly volatile in that it must be “refreshed” (i.e., recharged) every few hundred milliseconds in order to maintain the stored data. Static RAM (“SRAM”) will hold the data after one writing, so long as the power source is maintained; once the power source is disconnected, however, the data is lost. Thus, in these volatile memory configurations, information is only retained so long as the power to the system is not turned off. In general, these RAM devices can take up significant chip area and therefore may be expensive to manufacture and consume relatively large amounts of energy for data storage.

One type of programmable semiconductor non-volatile memory device suitable for use in such systems is a programmable read-only memory (“PROM”) device. One type of PROM, a write-once read-many (“WORM”) device, uses an array of fusible links. Once programmed, the WORM device cannot be reprogrammed.

Other forms of PROM devices include erasable PROM (“EPROM”) and electrically erasable PROM (EEPROM) devices, which are alterable after an initial programming. EPROM devices generally require an erase step involving exposure to ultra violet light prior to programming the device. Thus, such devices are generally not well suited for use in portable electronic devices. EEPROM devices are generally easier to program, but suffer from other deficiencies. In particular, EEPROM devices are relatively complex, are relatively difficult to manufacture, and are relatively large. Furthermore, a circuit including EEPROM devices must withstand the high voltages necessary to program the device. Consequently, EEPROM cost per bit of memory capacity is extremely high compared with other means of data storage. Another disadvantage of EEPROM devices is that, although they can retain data without having the power source connected, they require relatively large amounts of power to program. This power drain can be considerable in a compact portable system powered by a battery.

Another form of memory includes magnetic media such as that used in hard disk drive (HDD) units in computers and other electronic systems such as HDD-based MP3 players. Although this memory type works well for some present-day applications, the superparamagnetic limit, i.e., the density at which thermal fluctuations disturb magnetization, is thought to limit magnetic storage densities to below a half terabit per square inch and is likely to halt the decreasing cost per bit progress that has fueled the rapid growth of the storage industry in recent years. In addition, HDD units contain motors to rotate the medium and position the read/write (R/W) heads and these tend to make the technology power hungry and therefore a major source of energy drain in battery-operated systems.

Due, at least in part, to a rapidly growing numbers of compact, low-power portable computer systems and hand-held appliances in which stored information changes regularly, low energy read/write semiconductor memories have become increasingly desirable and widespread. Furthermore, because these portable systems often require data storage when the power is turned off, non-volatile storage devices are desired for use in such systems.

Accordingly, use of non-magnetic ways of information mass storage, such as microelectromechanical systems (MEMS) in the form of arrays of scanning probe tips, which address an electrically alterable medium, have been developed. One such approach to this type of data storage includes heating, by an electrical current, probe tips to create or destroy pits in a polymer medium. The presence or absence of these pits is detected using the same probes by detecting the subtle resistance change due to different amounts of heat flow in the two cases. Although data densities in excess of a half terabit per square inch have been demonstrated using this technology, there are still a great many challenges associated with this thermal approach to data storage, including the stability of the medium to repeated melting operations and the high currents used in the write and erase operations. Other approaches use phase change alloys (e.g., germanium antimony telluride or GST) to store the data by passing a current through the material to form either a crystalline or amorphous region under the tip by Joule heating, which can then be detected via the difference in resistance between the two phases. However, there are a number of problems associated with this approach too, including the high currents required to write and erase the data. Another issue that exists with both of these approaches is locating data on the medium after it has been written. Accurately repositioning the probes back to a particular address location requires some form of indexing on the medium itself. The indexing “marks” consume storage area and therefore reduce the capacity of the medium, a problem that gets worse as the storage density increases and the need for positional accuracy becomes more critical.

Accordingly, improved devices for storing information and systems including the devices are desired.

### SUMMARY OF THE INVENTION

The present invention provides programmable data storage devices for use with probe storage systems. Such device can be used to replace both traditional nonvolatile and volatile forms of memory in various appliances, such as computers, mp3 players, and the like.

The ways in which the present invention addresses various drawbacks of now-known devices and systems are discussed in greater detail below. However, in general, the present invention provides programmable devices and systems including devices that are relatively easy and inexpensive to manufacture, are relatively easy to program, require relatively little energy to program, and are relatively non-volatile.

In accordance with various embodiments of the invention, a programmable device includes an ion conductor and at least two electrodes, wherein at least one of the electrodes is in the form of a probe. The structure is configured such that when a bias is applied across two electrodes, one or more electrical properties of the structure change. In accordance with one aspect of this embodiment, a resistance across the device changes when a bias is applied across the electrodes. In accordance with other aspects of this embodiment, a capacitance or other electrical property of the structure changes upon application of a bias across the electrodes. In accordance with a further aspect of this embodiment, an amount of change in the programmable property is manipulated by altering an amount of energy used to program the device. One or more of these electrical changes may suitably be detected. Thus, stored information may be retrieved from a system including the devices.

In accordance with various additional embodiments of the invention, one of the first electrode and the probe is formed of a material including a conductive material that dissolves in an ion conductive material when a sufficient bias is applied across the electrodes (an oxidizable or soluble electrode) and the other electrode is relatively inert and does not dissolve during operation of the programmable device (an indifferent or inert electrode).

In accordance with one embodiment of the invention, a device includes a first electrode, an ion conductor layer overlying the first electrode, an insulating structure to isolate the ion conductor, and a probe electrode. In accordance with one aspect of this embodiment, the insulating structures are formed by depositing a layer of insulating material, forming vias within the insulating layer, depositing ion conductor material within the vias, and removing any excess ion conductor material. In accordance with another aspect, the isolating regions are formed by forming a first electrode, depositing ion conductor material overlying the first electrode, patterning and etching the ion conductor material to form ion conductor structures, and depositing an insulating layer to form insulating structures surrounding the ion conductor structures.

In accordance with another embodiment of the invention, a device includes a first electrode, an insulating structure to isolate the first electrode, an ion conductor layer overlying the first electrode, and a probe electrode. In accordance with one aspect of this embodiment, the insulating structures are formed by depositing a layer of insulating material, forming vias within the insulating layer, depositing first electrode material within the vias, and removing any excess first electrode material.

In accordance with another embodiment of the invention, a device includes a first electrode, an ion conductor structure overlying the first electrode, an insulating structure to isolate the ion conductor structure, a top electrode on the surface of the ion conductor, and a probe electrode. In accordance with one aspect of this embodiment, the insulating structures are formed by depositing a layer of insulating material on the first electrode, forming vias within the insulating layer, depositing ion conductor material overlying first electrode within the vias, removing any excess ion conductor material to below the surface of the insulating material, depositing the top electrode in the vias, and removing any excess top electrode material to pattern the top electrode in the vias.

In accordance with yet another embodiment of the invention, a device includes a first electrode, an ion conductor having isolation regions formed therein, and a probe electrode. In accordance with one aspect of this embodiment, an ion conductor layer includes naturally occurring columnar channels, where mass transport of the conductive ions can occur, such that the mass transport only occurs in these regions and not in the remainder of the ion conductor layer. In accordance with another aspect, the device includes a diffusion barrier interposed between at least part of the ion conductor and insulating structures or the ion conductor and at least part of one or both electrodes.

In accordance with another embodiment of the invention, a system includes a programmable device, including a first electrode, an ion conductor, and a second electrode, including a probe; a power source; and an actuator to move the probe relative to the ion conductor.

In accordance with yet another embodiment of the invention, a method of forming a programmable device includes providing a substrate, optionally forming an insulating layer overlying the substrate, forming a first electrode overlying the substrate, forming an ion conductor overlying the first electrode, and providing a probe electrode. In accordance with one aspect of this embodiment, the ion conductor is formed by first depositing a layer of material that conducts ions, depositing a layer of conductive material, and then using photo, thermal, and/or electrical diffusion means to diffuse the conductive material within the ion conductor.

### BRIEF DESCRIPTION OF THE DRAWING FIGURES

A more complete understanding of the present invention may be derived by referring to the detailed description and claims, considered in connection with the figures, wherein like reference numbers refer to similar elements throughout the figures, and:

FIGS. 1-4 illustrate a probe storage systems in accordance with various embodiments of the invention;

FIGS. 5(a) illustrates a current-voltage plot of a write operation on a cell in accordance with the present invention; and

FIG. 5(b) illustrates a resistance-voltage plot of a write operation on a cell in accordance with the present invention.

Skilled artisans will appreciate that elements in the figures are illustrated for simplicity and clarity and have not necessarily been drawn to scale. The dimensions of some of the elements in the figures may be exaggerated relative to other elements to help to improve understanding of embodiments of the present invention.

### DETAILED DESCRIPTION

The present invention generally relates to programmable probe-storage devices, to systems including the devices, and to methods of forming and using the devices and systems. Devices and systems of the present invention may be used to replace FLASH, DRAM, SRAM, PROM, EPROM, EEPROM, and HDD devices, or any combination of such memory.

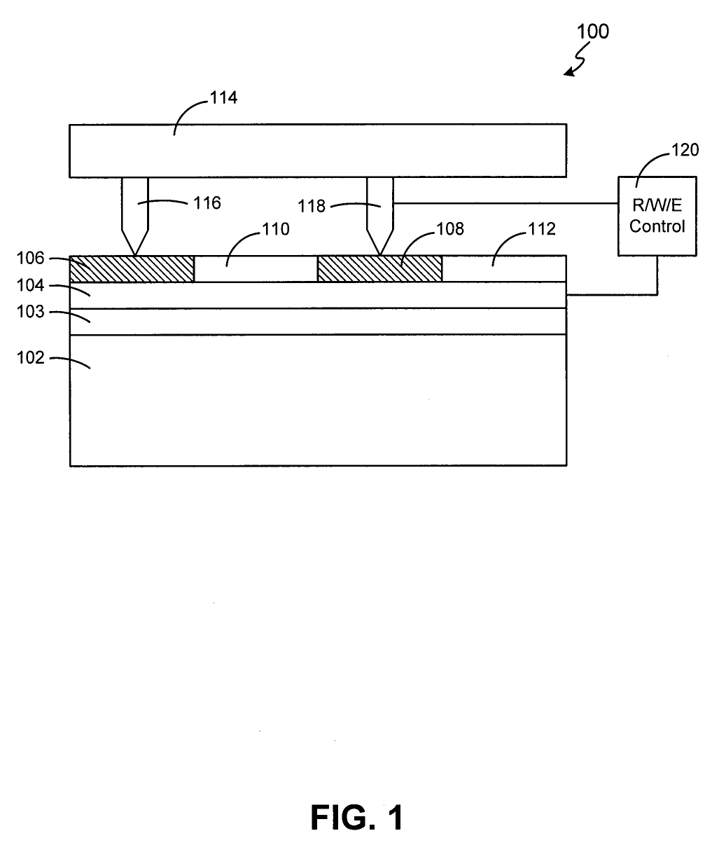

FIG. 1 illustrates a portion of a probe-storage system 100 in accordance with exemplary embodiments of the present invention. System 100 includes a substrate 102; an insulating layer 103; a first electrode 104; ion conductor structures 106, 108; insulating structures 110, 112; probe mechanism 114, including probes 116, 118; a read/write/erase control circuit 120; and an actuator (not shown) to move the probes relative to the substrate. Although illustrated with one (common) first electrode 104, two ion conductor structures, two insulating structures, and two probes, those skilled in the art appreciate that systems in accordance with the present invention may have several electrodes, ion conductor structures, insulating structures, and probes. Only a limited number of each is show in the figures for illustration purposes.

Programmable cells are defined by a first electrode 104, at least one ion conductor structure 106, 108, and at least one probe 116, 118. Generally, a cell is configured such that when a bias greater than a threshold voltage (V_{T}), discussed in more detail below, is applied across electrode 104 and at least one probe 116, 118, the electrical properties of the cell change. For example, as a voltage V≧V_{T} is applied across electrode 104 and a probe, conductive ions within the ion conductor begin to migrate and form a region having an increased conductivity compared to the bulk ion conductor (an electrodeposit or conductive region) at or near the more negative of the electrode and the probe. The amount of conductive material deposited depends on the magnitude and duration of the ion current, i.e., the total Faradic charge. The electrodeposit is electrically neutral and is stable in that it generally does not spontaneously dissolve. As the conductive region forms, the resistance between the electrode and the probe decreases, and other electrical properties such as capacitance of the cell also change.

In the absence of any barriers, which are discussed in more detail below, the threshold voltage required to grow the conductive region between the probe and the electrode, and thereby significantly reduce the resistance of the device, is approximately a few hundred millivolts. If the same voltage is applied in reverse, the conductive region dissolves back into the ion conductor and the device returns to a high resistance state.

In accordance with various embodiments of the invention, the volatility of programmable each cell can be manipulated by altering an amount of energy (e.g., altering time, current, voltage, thermal energy, and/or the like) applied during a write process, discussed in more detail below. The greater the amount of energy (having a voltage greater than the threshold voltage for the write process) applied during the write process, the greater the growth of the conductive region and hence the less volatile the memory. Conversely, relatively volatile, easily-erased, memory can be formed by supplying relatively little energy to the cell. Thus, relatively volatile memory can also be formed using the same or similar structures used to form nonvolatile memory, and less energy can be used to form the volatile/easily-erased memory.

Additionally, an amount of a conductive region is proportional to the reduced “on” voltage of the device, which may have virtually infinite states. The states can be quantized to obtain digital states of the device. A single cell can therefore be used to store a single bit or several bits of information. The erase resistance can also be quantized to increase the resistance of the cell from one state to another, or can be defined simply as the full off resistance of the device.

Referring again to FIG. 1, substrate 102 may include any suitable material. For example, substrate 102 may include semiconductive, conductive, semiinsulative, insulative material, or any combination of such materials. In accordance with one embodiment of the invention, substrate 102 includes a microelectronic devices formed using a portion of the substrate. Because the programmable cells can be formed over insulating or other materials, the programmable cells of the present invention are particularly well suited for applications where substrate (e.g., semiconductor material) space is a premium.

First electrode 104 may be formed of any suitable conductive material. For example, electrode 104 may be formed of doped polysilicon material or metal.

The configuration of first electrode may also vary according to application. In the illustrated embodiment, electrode 104 is common to both cells. In accordance with other embodiments, first electrode 104 is not common to multiple cells, and a probe or a top contact may be common to multiple cells. A more detailed discussion of common electrode configurations is described in U.S. Pat. No. 6,998,312, issued to Kozicki et al. on Feb. 14, 2006 the contents of which are hereby incorporated herein by reference.

In accordance with various exemplary embodiments of the invention, one of electrode 104 and probes 116,118 is formed of a conductive material that dissolves in ion conductor 106, 108 when a sufficient bias (V≧V_{T}) is applied across the electrode and probe (an oxidizable or soluble electrode) and the other electrode/probe is relatively inert and does not dissolve during operation of the programmable device (an indifferent or inert electrode). For example, electrode 104 may be an anode during a write process and be comprised of a material including silver that dissolves in the ion conductor and probe 116, 118 may be a cathode during the write process and be comprised of an inert material such as tungsten, nickel, molybdenum, platinum, metal silicides, conducting oxides, nitrides, and the like. In the case where the probe includes the soluble material, a probe tip may be coated with the soluble material and may be replenished by moving the probe to a “recharge” area that includes the soluble material, and applying a suitable bias across the recharge area and the probe to cause the conductive material to be plated onto the probe tip.

Having at least one electrode formed of a material including a material that dissolves in the ion conductor facilitates maintaining a desired dissolved material concentration within ion the conductor, which in turn facilitates rapid and stable conductive region formation within the ion conductor. Furthermore, use of an inert material for the other electrode (cathode during a write operation) facilitates electrodissolution of any conductive region that may have formed and/or return of the programmable device to an erased state after application of a sufficient voltage.

As noted above, programmable structures of the present invention may include one or more barrier or buffer layers interposed between at least a portion of the ion conductor and at least one of the electrode and the probe. Exemplary materials suitable for buffer and barrier layers are set for in U.S. Pat. No. 6,865,117, issued to Kozicki et al. on Mar. 8, 2005, the contents of which are incorporated herein by reference.

Ion conductor structures 106, 108 are formed of material that conducts ions upon application of a sufficient voltage. Suitable ion conductor materials include polymeric materials, glasses and semiconductor materials. In general, ion conductors in accordance with the present invention can conduct ions without requiring a phase change, can conduct ions at a relatively low temperature (e.g., below 125° C.), can conduct ions at relatively low electrical currents, have a relatively high transport number, and exhibit relatively high ion conductivity. In one exemplary embodiment of the invention, the ion conductor is formed of chalcogenide material (e.g., AsₓS₁₋ₓ, AsₓSe₁₋ₓ, AsₓTe₁₋ₓ, GeₓSe₁₋ₓ, GeₓS₁₋ₓ, GeₓTe₁₋ₓ, and MOₓ, where M is a transition metal). However, other materials may be used as an ion conductor in accordance with various embodiments of the invention. For example, polymeric ion conductors such as poly(ethylene oxide) may be used in accordance with the present invention.

The ion conductor material may also suitably include dissolved conductive material. For example, the ion conductor may comprise a solid solution that includes dissolved metals and/or metal ions. In accordance with one exemplary embodiment of the invention, the ion conductor material includes metal and/or metal ions dissolved in chalcogenide glass. An exemplary chalcogenide glass with dissolved metal in accordance with the present invention includes a solid solution of AsₓS₁₋ₓ-Ag, AsₓSe₁₋ₓ-Ag, AsₓTe₁₋ₓ-Ag, GeₓSe₁₋ₓ-Ag, GeₓS₁₋ₓ-Ag, GeₓTe₁₋ₓ-Ag, AsₓS₁₋ₓ-Cu, AsₓSe₁₋ₓ-Cu, AsₓTe₁₋ₓ-Cu, GeₓSe₁₋ₓ-Cu, GeₓS₁₋ₓ-Cu, and GeₓTe₁₋ₓ-Cu, where x ranges from about 0.1 to about 0.5, MOₓ-Ag, MOx-Cu, where M is a transition metal and x is 1, 2, or 3, other chalcogenide materials including silver, copper, combinations of these materials, and the like.

Insulating structures 110, 112 and layer 103 are formed of material that prevents undesired diffusion of electrons and/or ions across portions of a cell or between cells. In accordance with one embodiment of the invention, the insulating material includes silicon oxide, silicon nitride, silicon oxynitride, polycrystalline silicon, amorphous silicon, amorphous carbon, polymeric materials such as polyimide or parylene, or any combination thereof. Structures 110, 112 may be desirable because, among other reasons, the structures allow for relatively small cells; e.g., on the order of 10 nanometers, to be formed. The insulating material structures facilitate isolating various cells from each other and from other electrical components.

Circuit 120 may include any. suitable circuit for providing the requisite voltage for write, read, and erase operations. One such circuit is described in U.S. patent application Ser. No. ______, filed Mar. 13, 2006, and entitled READ, WRITE, AND ERASE CIRCUIT FOR PROGRAMMABLE MEMORY DEVICES, the contents of which are incorporated by reference.

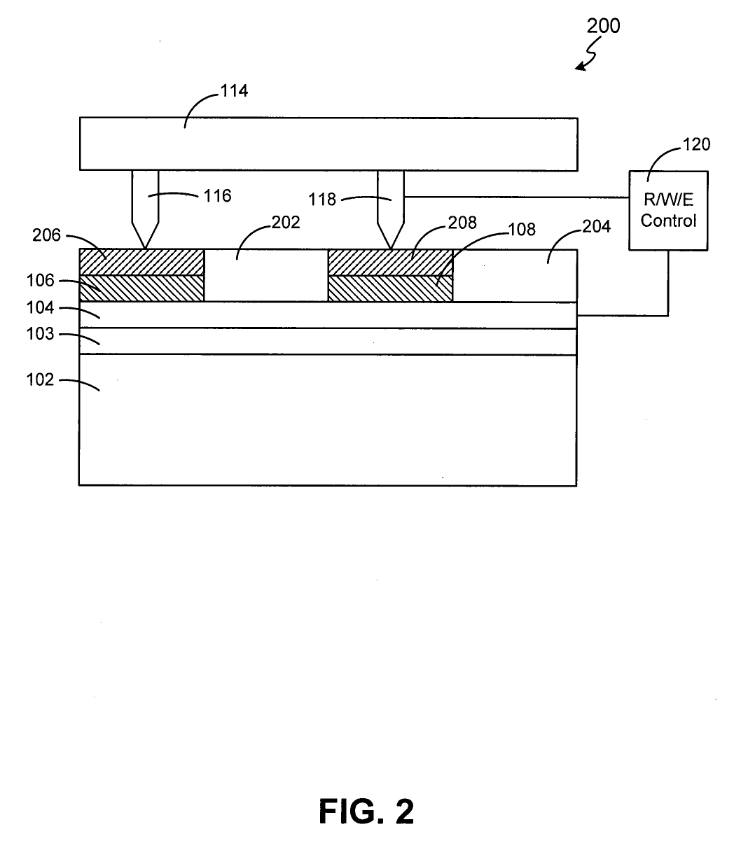

FIG. 2 illustrates another system 200 in accordance with various embodiments of the invention. System 200 is similar to system 100, except system 200 includes insulating structures 202, 204 (rather than 110, 112) and includes contacts 206, 208. Providing isolated contacts 206, 208 overlying the ion conductor may be desirable because the contacts protect the upper surface of the ion conductor and facilitate electrical contact between the respective probe and the ion conductor.

Contacts 206, 208 may be formed of any conductive material and are preferably formed of a metal, alloy, or composition including aluminum, tungsten, molybdenum, nickel, titanium nitride, tungsten nitride, or a combination thereof (e.g., multiple layers of such materials). Contacts 206, 208 may also be formed of soluble electrode material. In this case, electrode 104 is formed of inert material and contact 206 is preferably formed of a combination of soluble electrode material proximate the ion conductor and inert material overlying the soluble electrode material.

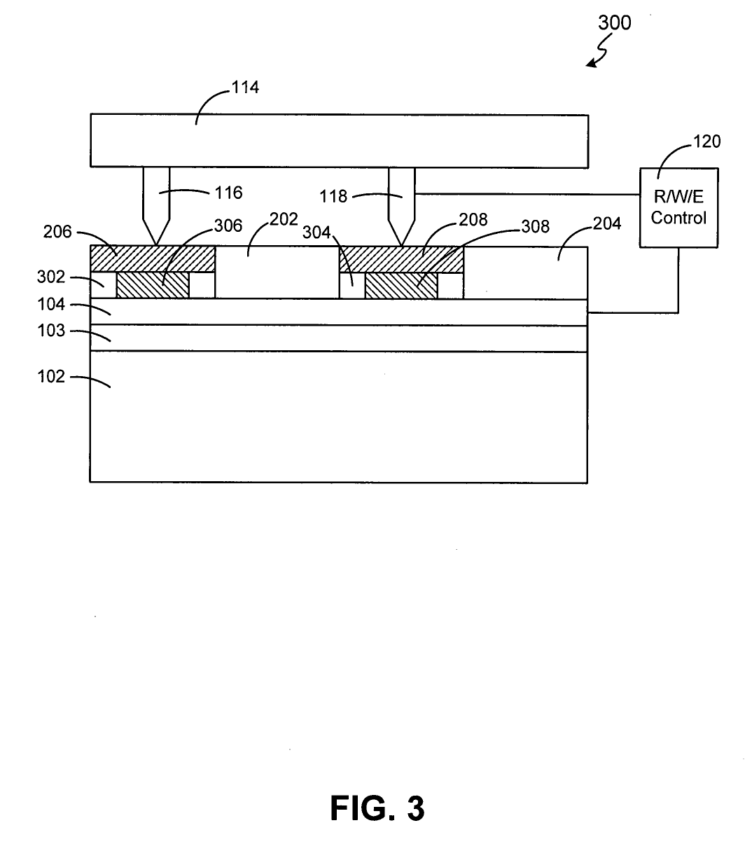

FIG. 3 illustrates another system 300 in accordance with yet further embodiments of the invention. System 300 is similar to system 200, except system 200 includes diffusion barriers 302, 304 interposed between ion conductor structures 306, 308 and insulating structures 202, 204. Inclusion of an insulating diffusion barrier in this way allows for increased cell density. Insulating or conducting barrier layers (not shown) may additionally be used between at least part of the ion conductor and one or both of the electrodes.

Suitable materials for diffusion barriers 302, 304 include insulating material such as silicon dioxide, silicon nitride, a combination thereof, or the like, and conducting materials such as titanium nitride, tungsten nitride, titanium-tungsten and the like.

Alternatively, the partitioning of a large-area electrolyte into multiple (e.g., nanoscale) columns may be achieved by forming the solid electrolyte in an insulating oxide or nitride barrier structure such as, that formed e.g., via the anodic oxidation of aluminum. Or, nanopatterning of the electrolyte can be achieved using optical or electron holography. A holographic pattern can be used to either expose a thin resist layer to create a nanoscale surface mask or to directly expose a base glass-silver bilayer to promote Ag dissolution only in nanoscale regions of the glass. An isotropic is then used to form nanoscale columns of the electrolyte and the spaces between the columns are filled in with insulating material.

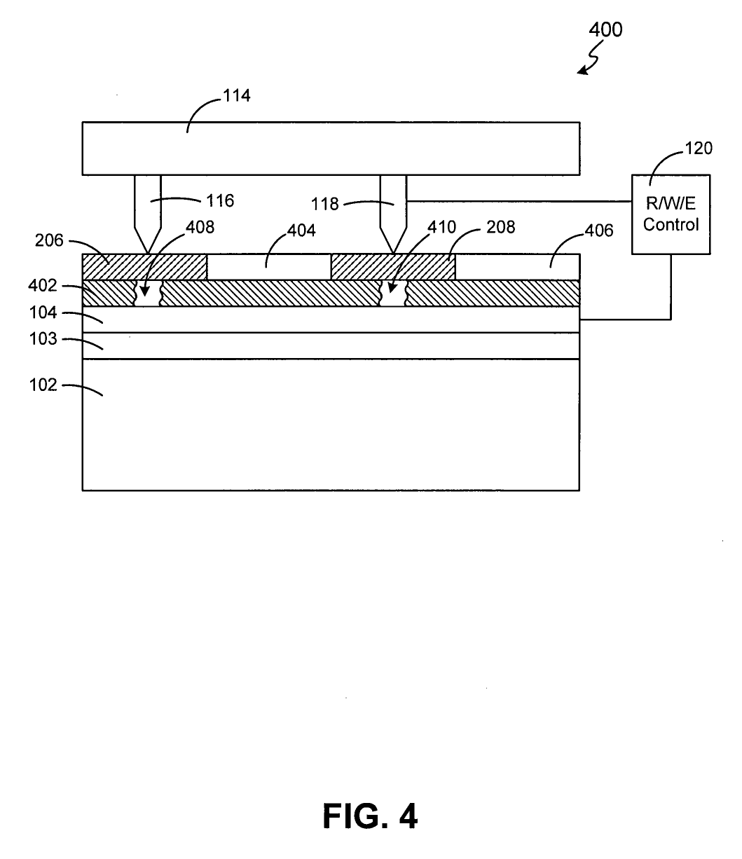

FIG. 4 illustrates another system 400 in accordance with additional embodiments of the invention. System 400 is similar to system 200, except system 400 includes an ion conductor layer which includes micro channels or voids 408, 410 to facilitate conductive region growth. Because growth of electrodeposits preferentially forms between the probe and the electrode along these fissures or channels relative to the bulk ion conductor layer, insulating structures, which isolate regions of the ion conductor material, may not be required. In this case, isolating structures 404, 406 do not extend through ion conductor layer 402.

Information may be stored using the systems described herein by manipulating one or more electrical properties of the cells within the systems. For example, a resistance of a cell may be changed from a “0” or off state to a “1” or on state during a suitable write operation. Similarly, the cell may be changed from a “1” state to a “0” state during an erase operation.

Write Operation

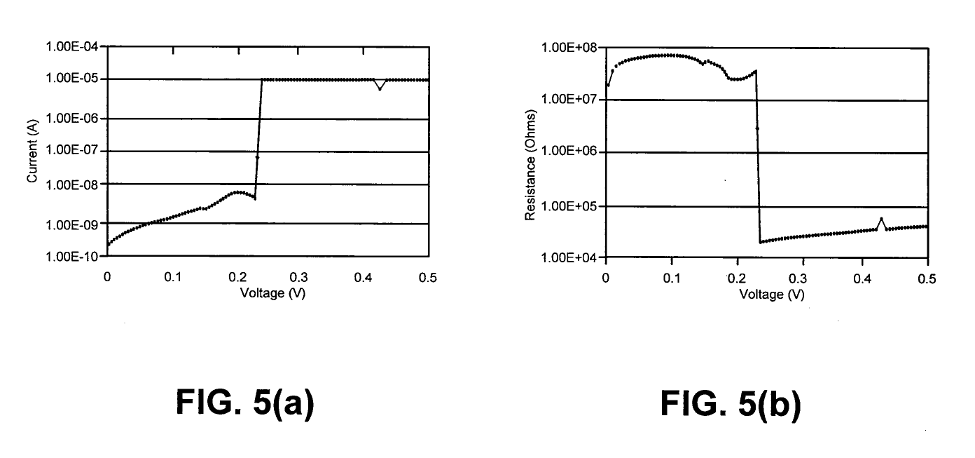

FIG. 5(a) illustrates current-voltage characteristics of a programmable cell in accordance with various embodiments of the present invention. In the illustrated embodiment, a 40 mn thick Ag—Ge—Se film on a Ag electrode using a tungsten probe as the top electrode, was used. As illustrated, current through a cell in an off state begins to rise upon application of a bias of over about 200 mV; however, once a write step has been performed (i.e., a conductive regions has formed), the resistance through the ion conductor drops significantly, as illustrated in FIG. 5(b). As noted above, when a probe is coupled to a more negative end of a voltage supply, compared to electrode 104, the conductive region begins to form near the probe or contact and grow toward electrode 104. The write threshold of the cells can be altered, by for example, using barrier layers as described above.

Read Operation

A state of the device (e.g., 1 or 0) may be read, without significantly disturbing the state, by, for example, applying a forward or reverse bias of magnitude less than a voltage threshold for electrodeposition or by using a current limit which is less than or equal to the minimum programming current (the current which will produce the highest of the on resistance values). In the illustrated case, the voltage is swept from 0 to about 0.5 V and the current rises up to the set limit, indicating a low resistance (ohmic/linear current-voltage) “on” state. Another way of performing a non-disturb read operation is to apply a pulse, with a relatively short duration, which may have a voltage higher than the electrochemical deposition threshold voltage such that no appreciable Faradaic current flows, i.e., nearly all the current goes to polarizing/charging the device and not into the electrodeposition process.

Erase Operation

A programmable cell may suitably be erased by reversing a bias applied during a write operation, wherein a magnitude of the applied bias is equal to or greater than the threshold voltage for electrodeposition in the reverse direction. In accordance with an exemplary embodiment of the invention, a sufficient erase voltage (V≧V_{T}) is applied to a cell for a period of time which depends on the strength of the initial connection but is typically less than about 1 millisecond to return the cell to its “off” state having a resistance well in excess of a million ohms.

As noted above, multiple bits of data may be stored within a single programmable cell by controlling an amount of a conductive region or electrodeposit, which is formed during a write process. An amount of electrodeposit that forms during a write process depends on a number of coulombs or charge supplied to the structure during the write process, and may be controlled by using a current limit power source. In this case, a resistance of a programmable structure is governed by Equation 1, where Rₒₙ is the “on” state resistance, V_{T} is the threshold voltage for electrodeposition, and I_{LIM} is the maximum current allowed to flow during the write operation.

$${R}_{on} = \frac{{V}_{T}}{{I}_{LI M}} \qquad Equation 1$$

In practice, the limitation to the amount of information stored in each cell will depend on how stable each of the resistance states is with time. For example, if a structure has a programmed resistance range of about 3.5 kΩ and a resistance drift over a specified time for each state is about ±250 Ω, about 7 equally sized bands of resistance (7 states) could be formed, allowing 3 bits of data to be stored within a single structure. In the limit, for near zero drift in resistance in a specified time limit, information can be stored as a continuum of states, i.e., in analog form.

Method of Forming the Structures

In accordance with one embodiment of the invention, cells are formed by forming electrode 104 on substrate 102 and insulating layer 103. Electrode 104 may be formed using any suitable method such as, for example, depositing a layer of electrode 104 material, patterning the electrode material, and etching the material to form electrode 104 (a common electrode in the illustrated embodiments). Insulating layer structures (e.g., structures 110, 112) may be formed by depositing insulating material onto electrode 130 and substrate 110 and forming vias in the insulating material using appropriate patterning and etching processes. Ion conductor structures 106, 108 may then be formed within the insulating layer vias by depositing ion conductor material within the vias. Such ion conductor material deposition may be selective—i.e., the material is substantially deposited only within the via, or the deposition processes may be relatively non-selective. If one or more non-selective deposition methods are used, any excess material remaining on a surface of insulating layer may be removed using, for example, chemical mechanical polishing and/or etching techniques. Any barrier structures may similarly be formed using any suitable deposition and/or etch processes and/or mechanical processes. In accordance with one aspect of this embodiment, during the removal of excess ion conductor material, the ion conductor material is removed to below the surface of the via, top electrode or contact material is deposited into the top portion of the via, and any excess top electrode/contact material is removed to form patterned, isolated top contacts/electrodes.

A solid solution suitable for use as the ion conductor may be formed in a variety of ways. For example, the solid solution may be formed by depositing a layer of conductive material such as metal over a chalcogenide glass without breaking a vacuum and exposing the metal and glass to thermal and/or photo dissolution processing. In accordance with one exemplary embodiment of the invention, a solid solution of Ge₃Se₇-Ag is formed by depositing Ge₃Se₇ onto a substrate, depositing a thin film of Ag onto the Ge₃Se_{7,}, and exposing the films to light having energy greater than the optical gap of the Ge₃Se_{7,}—e.g., light having a wavelength of less than about 500 nanometers (e.g., light having a wavelength of about 436 nm at about 4.5 mW/cm²). With this process the chalcogenide glass can incorporate over 30 atomic percent of silver and remain macroscopically glassy and microscopically phase separated.

In accordance with another embodiment of the invention, a solid solution may be formed by depositing one of the constituents from a source onto a substrate or another material layer and reacting the first constituent with a second constituent. For example, germanium (preferably amorphous) may be deposited onto a portion of a substrate and the germanium may be reacted with H₂Se to form a Ge—Se amorphous film. Similarly, arsenic can be deposited and reacted with the H₂Se gas, or arsenic or germanium can be deposited and reacted with H₂S gas. Silver or other metal can then be added to the material as described above.

In accordance with alternative embodiments of the invention, solid solutions containing dissolved metals may be directly deposited onto a substrate and the electrode then formed overlying the ion conductor. For example, a source including both chalcogenide glass and conductive material can be used to form the ion conductor using physical vapor deposition or similar techniques.

Although the present invention is set forth herein in the context of the appended drawing figures, it should be appreciated that the invention is not limited to the specific form shown. For example, although the systems are illustrated with a common electrode, such is not required to practice the present invention. Furthermore, although only some of the devices are illustrated as including buffer structures, such structures may be added to any of the systems of the present invention. Various other modifications, variations, and enhancements in the design and arrangement of the method and apparatus set forth herein, may be made without departing from the spirit and scope of the present invention as set forth in the appended claims.

I claim:

1. A cell for use in a probe storage system, the cell comprising:
a first electrode;
an ion conductor overlying the first electrode;
an insulating structure adjacent the ion conductor and overlying the first electrode; and
a probe movable relative the ion conductor.

2. The cell of claim 1, wherein the first electrode comprises material that is soluble in the ion conductor.

3. The cell of claim 1, wherein the ion conductor comprises a solid solution selected from the group consisting of AsₓS₁₋ₓ-Ag, GeₓSe₁₋ₓ-Ag, GeₓS₁₋ₓ-Ag, AsₓS₁₋ₓ-Cu, GeₓSe₁₋ₓ-Cu, GeₓS₁₋ₓ-Cu, where x ranges from about 0.1 to about 0.5, MOₓ-Ag, MOₓ-Cu, where M is a transition metal and x is 1, 2, or 3.

4. The cell of claim 1, further comprising a contact overlying the ion conductor and adjacent the ion conductor.

5. The cell of claim 1, further comprising a barrier structure interposed between at least part of the ion conductor and at least one of the insulating structure, the first electrode, and the probe.

6. The cell of claim 5, wherein the barrier structure comprises conductive material.

7. The cell of claim 5, wherein the barrier structure comprises insulating material.

8. The cell of claim 1, wherein the first electrode electrically couples a plurality of cells.

9. The cell of claim 1, wherein the first electrode comprises a material selected from the group consisting of silver and copper.

10. A programmable cell for use with a probe storage system, the cell comprising:
a first electrode;
an ion conductor layer overlying the first electrode, wherein the ion conductor layer includes channels to facilitate conductive region growth; and
a probe.

11. The programmable cell of claim 10, wherein the probe and the ion conductor are movable with respect to each other.

12. The programmable cell of claim 10, further comprising a contact formed overlying the ion conductor layer.

13. The programmable cell of claim 12, further comprising an isolating structure adjacent the contact and overlying the ion conductor layer.

14. The programmable cell of claim 12, wherein the contact comprises material that is soluble in the ion conductor layer.

15. The programmable cell of claim 10, wherein the first electrode comprises material that is soluble in the ion conductor layer.

16. The programmable cell of claim 10, further comprising a barrier layer interposed between at least part of the ion conductor layer and one of the first electrode and the probe.

17. A system for reading, writing, and erasing information, the system comprising:
a cell comprising a first electrode, an ion conductor, an insulating structure adjacent the ion conductor, and a probe movably and disengageably electrically coupled to the ion conductor; and
an actuator for moving the probe relative the first electrode.

18. The system of claim 17, further comprising a circuit for providing a read, a write and an erase voltage to the cell.

19. The system of claim 17, further comprising a contact overlying the ion conductor.

20. A method or programming a probe data system, the method comprising the steps of:
providing a cell comprising a first electrode, an ion conductor, and a probe;
applying a bias across the cell to change an electrical property of the cell, wherein the electrical property has more than two states; and
reading a change of the electrical property.

21. A method or programming a probe data system, the method comprising the steps of:
providing a cell comprising a first electrode, an ion conductor, and a probe, wherein the probe comprises material that is soluble in the ion conductor; and
replenishing the soluble material on the probe by moving the probe to a replenishing area and plating soluble material onto the probe.
